(19) United States
(12) Patent Application Publication
(10) Pub. No.: US 2010/0201351 A1
(43) Pub. Date: Aug. 12, 2010

(54) APPARATUS AND METHOD FOR SENSING ORIENTATION

(76) Inventor: Mark Clymer, Mystic, CT (US)

Correspondence Address: MICHAUD-Kinney Group LLP, 306 INDUSTRIAL PARK ROAD, SUITE 206, MIDDLETOWN, CT, 06457, US

(21) Appl. No.: 12/689,298

(22) Filed: Jan. 19, 2010

Related U.S. Application Data
(60) Provisional application No. 61/145,769, filed on Jan. 20, 2009.

(51) Int. Cl. G01B 7/14; G01R 33/07; H01F 7/02

(52) U.S. Cl. 324/207.2; 324/251; 29/602.1

(57) ABSTRACT

A magnetometer includes a spherical magnet member movably disposed within an enclosure. There is a plurality of Hall effect sensors on the enclosure and circuitry responsive to the plurality of Hall effect sensors. The circuitry is configured to indicate changes in the relative orientation of the spherical magnet member and the plurality of Hall effect sensors. A change in orientation of a movable structure is sensed by placing a magnetometer on the movable structure, allowing the spherical magnet member in the enclosure to assume an initial orientation therein; and monitoring the circuitry that is responsive to the Hall effect sensors. Alternatively, the magnetometer is placed on a stationary structure in sensing proximity to the movable structure.

### CROSS-REFERENCE TO RELATED APPLICATION

This application claims the benefit of U.S. provisional application No. 61/145,769 filed Jan. 20, 2009, which is incorporated herein by reference in its entirety.

### FIELD OF THE INVENTION

The present disclosure relates generally to an apparatus and method of sensing changes in orientation of a structure, relative to an initial orientation.

### BACKGROUND

In a variety of situations it is desirable to be able to detect a change in orientation of a structure, relative to an initial orientation. For example, in positioning a drill bit used for drilling deep wells such as oil wells, it can be important that the drill bit maintain a particular orientation so that optimum drill performance is maintained and so that targeted geological locations are reached by the drill. Orientation sensing is important in devices used in other applications as well, including navigation, proximity sensing, angular and linear positioning, 3-D positioning, large air gap speed sensing, frequency sensing, gear speed sensing, valve position sensing and positioning of deep drilling devices in a wide array of security, commercial, military, and consumer markets. In many such applications, monitoring the orientation of at least a portion of a device allows the user to improve the device and the results obtained in its use by improving the devices' performance, prolonging the useful life, enhancing safety, reducing wear, avoiding damage to other structures, etc.

### SUMMARY OF THE INVENTION

The present invention resides in one aspect in a magnetometer which includes a spherical magnet member movably disposed within an enclosure, a plurality of Hall effect sensors on the enclosure, and circuitry responsive to the plurality of Hall effect sensors. The circuitry is configured to indicate changes in the relative orientation of the spherical magnet member and the plurality of Hall effect sensors.

The present invention resides in another aspect in a method of making a magnetometer by providing a spherical magnet movably disposed within an enclosure, disposing a plurality of Hall effect sensors on the enclosure; and providing circuitry responsive to the plurality of Hall effect sensors, the circuitry being configured to indicate changes in the relative orientation of the spherical magnet member and the plurality of Hall effect sensors.

According to another aspect, the invention provides a method of sensing a change in orientation of a movable structure, by placing a magnetometer as defined herein on the movable structure, allowing the spherical magnet member in the enclosure to assume an initial orientation therein; and monitoring the circuitry that is responsive to the Hall effect sensors.

In another aspect, the invention resides in a method of sensing a change in orientation of a movable structure which includes placing a magnetometer as defined herein on a stationary structure in sensing proximity to the movable structure, allowing the spherical magnet member in the enclosure to assume an initial orientation therein, and monitoring the circuitry that is responsive to the Hall effect sensors.

### BRIEF DESCRIPTION OF THE DRAWINGS

FIG. 1A is a perspective view of a magnetometer.

FIG. 1B is a cross sectional view of one embodiment of a spherical magnet member as described herein.

FIG. 2A is a cross sectional view of the magnetometer.

FIG. 2B is a partial cross sectional view of another embodiment of a magnetometer.

FIG. 2C is a partial cross sectional view of another embodiment of a magnetometer.

FIG. 3 is perspective view of a enclosure.

FIG. 4 is a schematic view of a flexible substrate.

FIG. 5 is a cross sectional view of a weighted spherical magnet.

FIG. 6 is a schematic view of a magnetometer on a movable structure.

FIG. 7 is a schematic view of a magnetometer on a stationary structure, in sensing proximity to a movable structure.

### DETAILED DESCRIPTION

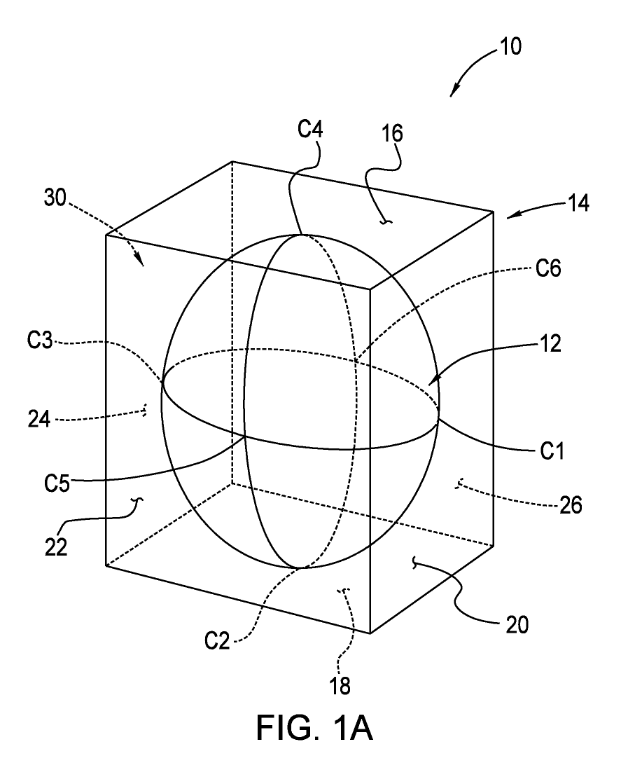

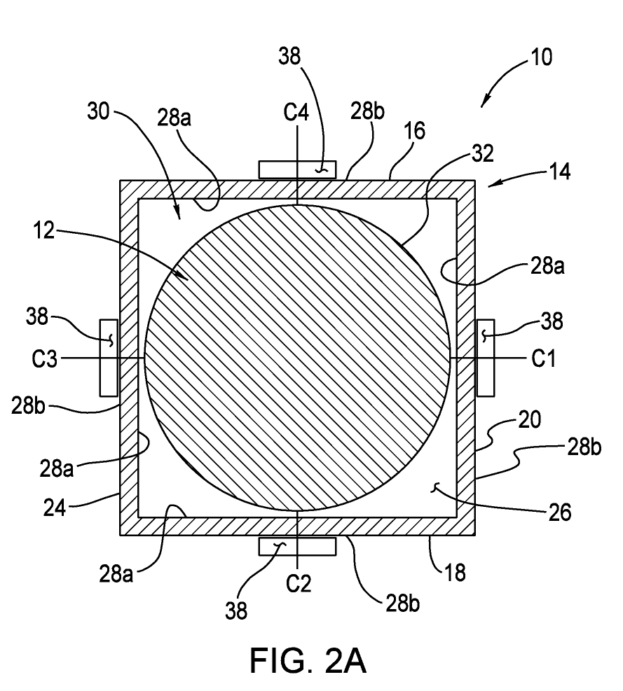

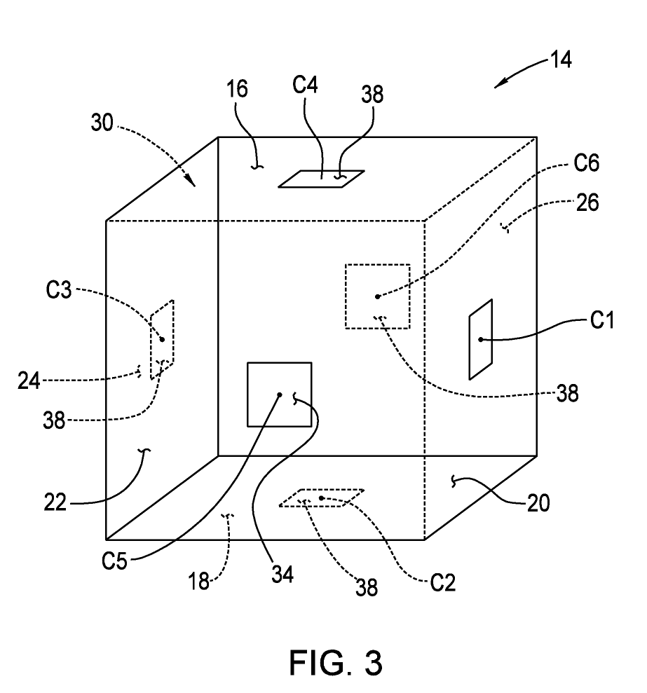

In one embodiment, a magnetometer indicated at 10 in FIG. 1A and FIG. 2A includes a spherical magnet member 12 positioned in an enclosure 14. The magnetometer 10 has utility in such things as, but not limited to, position and motion sensing, including navigational, 3-axis orientation, proximity sensing, angular and linear positioning, large air gap speed sensing, frequency sensing, gear speed sensing, valve position sensing and positioning of deep drilling devices in a wide array of security, commercial, military, and consumer markets.

As illustrated in FIG. 1, FIG. 2A and FIG. 3, the enclosure 14 is cube-shaped, having six equally sized walls, namely two square walls 16, 18 separated by and connected to one another by four side walls 20, 22, 24, 26 which are also square. The square walls 16, 18 and the side walls 20, 22, 24, 26 have respective interior surfaces 28a which collectively define an interior 30 of the enclosure 14 as well as exterior surfaces 28b at the exterior of the enclosure. While the enclosure 14 is described as being cube-shaped and having six equally sized walls, the present invention is not limited in this regard as enclosures having any other shape, such as but not limited to, rectangular, diamond, oval, octagon and pyramid shaped enclosures can be employed without departing from the broader aspects of the present invention.

The spherical magnet member 12 has an outside surface 32 seen in FIG. 2. The diameter of the spherical magnet member 12 is sized such that the outside surface 32 engages one or more of the interior surfaces 28a of the six walls 16, 18, 20, 22, 24, 26. In one embodiment, the interior surfaces 28a are flat and the outside surface 32 engages one or more of the flat interior surfaces at or near a center point C1-C6 of each of the six walls 16, 18, 20, 22, 24, 26. However, the invention is not limited in this regard as in other configurations, the spherical magnet member 12 may engage the enclosure 14 at one or more positions other than the center points C1-C6.

While FIG. 2 shows the spherical magnet member 12 engaging flat interior surfaces 28a, the invention is not limited in this regard, and in other embodiments the interior surfaces 28a have centrally positioned spherical depressions in which the outside surface of the spherical magnet member slides. In still other embodiments, a bearing such as a micro-sapphire bearing (not shown) is provided between the outside surface 32 and the interior surfaces 28a, and/or there may be one or more gyroscopic contact points (not shown) between the spherical magnet member 12 and the enclosure 14, without departing from the broader as aspects of the present invention. In still further embodiments, desired movability of the spherical magnet member 12 may be ensured by placing the spherical magnet member in a spherical cavity and supporting the spherical magnet member on a bed of free-floating sapphire bearings poured into an interstitial cavity defined between the spherical magnet member and the walls of the spherical cavity.

The magnetometer 10 does not have a lubricant between the spherical magnet member 12 and the enclosure 14, as the spherical magnet member 12 has a strength sufficient to operate without the use of any lubricant or lubricious material, but the invention is not limited in this regard, and in other embodiments a lubricant can be disposed between the outside surface 32 and the interior surfaces 28a of the enclosure 14 to reduce the friction therebetween and thus facilitate relative motion between the spherical magnet member 12 and the enclosure 14. Any suitable lubricant may be used, such as, a layer of polytetrafluororethylene (PTFE) (e.g., Teflon®), available from E. I. du Pont de Nemours and Company) and/or a colloidal suspension of magnetic particles in a liquid carrier (a “magnetic liquid”, such as MagnaView™ liquid, available from United Nuclear Scientific LLC.) For example, in one embodiment shown in FIG. 2B, one or more of the interior surfaces 28a of the enclosure 14 have a layer 34 of PTFE applied thereon at least at the point of engagement with the spherical surface 32. In another embodiment shown in FIG. 2C, a magnetic liquid 36 is allowed to coat the spherical magnet member and will provide a lubricating effect. When using a magnetic liquid as the lubricant, the enclosure 14 is sealed to prevent the lubricant from evaporating or drying out.

In a specific embodiment, the diameter of the spherical magnet member 12 is about ⅛ inch, but the invention is not limited in this regard as magnet members of various sizes can be employed.

In a specific embodiment, the spherical magnet member 12 comprises a high-energy (e.g., 44 megagaussOersted (MGOe)) neodymium-iron magnetic material, but the invention is not limited in this regard, and in other embodiments the spherical magnet member may comprise other magnetic material.

In the specific embodiment shown in FIG. 1B, the spherical magnet member 12′ comprises a spherical permanent magnet 12a which is plated with a material 12b comprising nickel and chromium. However, the invention is not limited in this regard, and in other embodiments other plating material 12b may be used or the spherical permanent magnet 12a may not have a plating material.

As shown in FIG. 2A and FIG. 3, a Hall effect sensor 38 is disposed on an outside surface 28b of each of the six walls 16, 18, 20, 22, 24, 26. For example, a linear Hall effect sensor having a total voltage swing of approximately 5 volts (V_{CC}) can be employed, but the invention is not limited in this regard, and in other embodiments other suitable Hall effect sensors may be used. When not exposed to a magnetic field, the output voltage of the Hall effect sensors 38 is about one half of V_{CC} or about 2.5 volts. The output voltage will increase or decrease as the polarity and/or orientation of the spherical magnet member 12 changes from the fundamental polarity and initial orientation, respectively. In one embodiment, the linear Hall effect sensors 38 include integrated circuits featuring onboard signal conditioning and temperature compensation and are connected to a voltage source, for example a 5 volt power supply. The present invention is not limited to the use of linear Hall effect sensors, however, as other magnetic sensors such as magnetoresistive sensors, giant magnetoresistive (GMR) sensors, inductive coils, and the like may also be employed. Switching magnet sensors, such as Hall effect sensors capable of switching between on and off states, are also within the scope of the present invention.

In a specific embodiment, each Hall effect sensor 38 is centered on the respective center points C1-C6 of the outside surfaces of the six walls 16, 18, 20, 22, 24, 26. However, the invention is not limited in this regard, and in other embodiments one or more Hall effect sensors 38 may be positioned off-center on one or more of the six walls 16, 18, 20, 22, 24, 26, and either externally or internally of the enclosure 14.

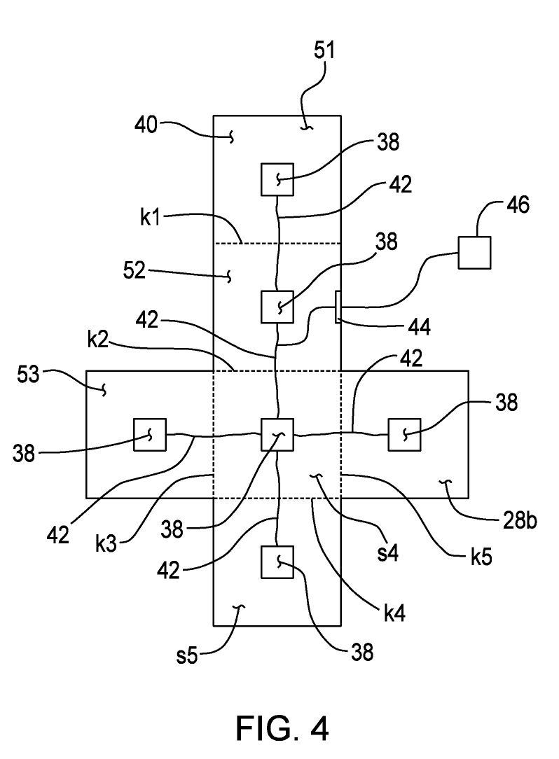

As illustrated in FIG. 4, the Hall effect sensors 38 are positioned on a flexible substrate 40 together with circuit connections 42 which connect the Hall effect sensors to each other and/or to a connector 44 for communicating with an circuit 46. Preferably, the substrate 40 comprises an electrically nonconducting material. In certain embodiments, the flexible substrate 40 may comprise a flexible film made from a polymeric material. Suitable polymeric materials include polyester materials such as a PET (polyethyleneterephthalate) and polyimide materials, such as MYLAR® or KAPTON® polymer materials, both available from E.I. du Pont de Nemours and Company, but the invention is not limited in this regard, and in other embodiments any other suitable substrate material or combination of materials may be used.

In one embodiment, the flexible substrate 40 is configured in a cross-shaped pattern having six segments S1-S6 each configured to fit on each of the six outside surfaces 28b of the enclosure 14. The flexible substrate 40 has creases K1-K5 formed between adjacent segments S1-S6. The flexible substrate 40 is folded along the creases K1-K5 and is disposed around the enclosure 14 to position the Hall effect sensors 38 on the walls 16, 18, 20, 22, 24 and 26 as described above.

The circuit 46 includes the voltage source for supplying power to the Hall effect sensors 38 and one or more microprocessors for processing outputs and data from the Hall effect sensors. In one embodiment, the circuit 46 is configured to receive signals from a plurality of the Hall effect sensors 38 and to determine the extent to which a change has occurred between the relative positions of the spherical magnet member 12 and the enclosure 14 relative to the initial orientation. In addition, the circuitry 46 and/or the Hall effect sensors are capable of being programmed so that operational settings and parameters can be changed depending on the use of the magnetometer 10.

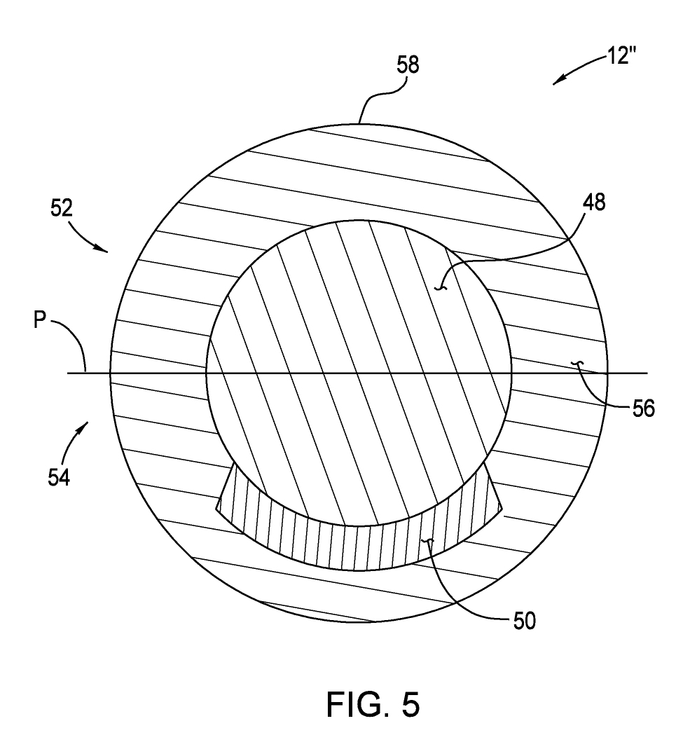

In one embodiment shown in FIG. 5, a spherical magnet member 12″ comprises a permanent magnet 48 with a ballast element 50 thereon. The spherical magnet member 12″ is generally spherical in configuration and has a first hemisphere 52 and a second hemisphere 54 positioned on opposing sides of a central plane P. The ballast element 50 is secured to a portion of the permanent magnet 48 in the second hemisphere 54. In one embodiment, the permanent magnet 48 is spherical in shape, but the invention is not limited in this regard, and in other embodiments the permanent magnet 48 may have other configurations. The permanent magnet 48 and the ballast element 50 are coated with a shell 56 such that the magnet member 12″ is has spherical outside surface 58. The ballast element 50 has a size, density and mass selected such that the second hemisphere 54 has a mass greater than that of the first hemisphere 52. The spherical magnet member 12″ can be positioned in the enclosure 14 as described above for the spherical magnet member 12. Because the second hemisphere 54 has a mass greater than that of the first hemisphere 52, gravity forces the spherical magnet member 12″ to assume an initial orientation wherein the plane P is horizontal and the first hemisphere is positioned above the second hemisphere. The present invention is not limited to the use of a ballast element 50 to impart a greater mass to one hemisphere of the spherical magnet member 12″ as compared to the other hemisphere, however, as material may be removed from one hemisphere (e.g., by drilling) thereby resulting in a void that is subsequently filled with a lightweight foam (or similar material), thus imbalancing the spherical magnet member 12″ and allowing gravity to force the spherical magnet member to assume the initial orientation.

As mentioned above, while the permanent magnet 48 may be spherical in shape as described above, the present invention is not limited in this regard, and in other configurations the permanent magnet may have other configurations. For example, the spherical magnet member 12′ may comprise a hemispherical shaped magnet (not shown) positioned in the first hemisphere 52 and a hemisphere shaped ballast element (not shown) having a mass greater than the hemisphere shaped magnet, positioned in the second hemisphere. Still other configurations can be utilized as well to provide the permanent magnet with an initial orientation, without departing from the broader aspects of the present invention.

While gravity is described as causing the spherical magnet member 12″ to assume an initial position wherein the first hemisphere is positioned above the second hemisphere, the present invention is not limited in this regard as other forces applied to the spherical magnet member 12″ including but not limited to magnetic fields and centrifugal forces can also affect the initial orientation of the spherical magnet assembly.

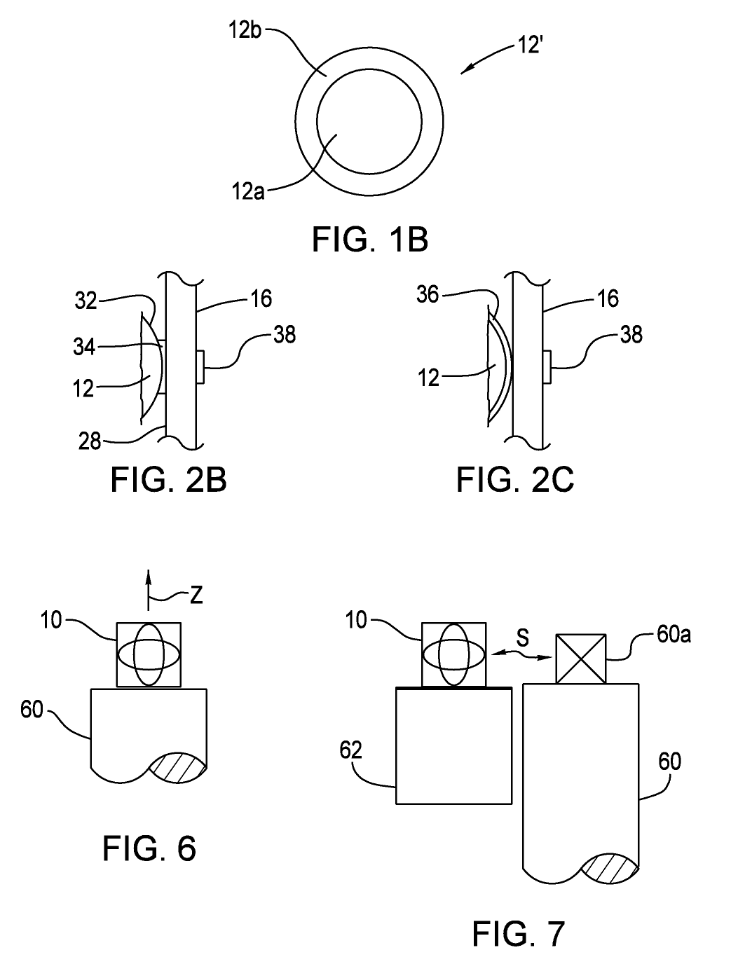

In one embodiment of a method of using the magnetometer 10, the magnetometer is mounted on a movable structure 60 as indicated in FIG. 6, such as a drill head, a gear, a wheel or any other item, the change in position and/or motion of which is to be sensed. For example, movable structure 60 may be a drill head of an oil well drilling system, and the magnetometer 10 may be used for determining the position of the drill head with respect to one or more reference points. Initially, during operation, the spherical magnet member 12 assumes its initial orientation i.e., the spherical magnet member 12 orients itself in response to the Earth's gravity and/or to a major vector of the prevailing magnetic field in which the magnetometer 10 is placed, thereby assuming an initial orientation relative to the enclosure 14 and to the Hall effect sensors 38. In the absence of another applied magnetic field, the spherical magnet member will tend to orient itself to a major vector of the earth's magnetic field, the Z-field (indicated at Z), which in temperate latitudes, is approximately 17 degrees off vertical. The earth's magnetic field averages approximately ½ gauss over the surface of the earth.

When the movable structure 60 moves relative to the prevailing magnetic field, the spherical magnet member 12 will maintain the initial orientation while the enclosure 14 and the Hall effect sensors 38 thereon move with the movable structure 60. For example, when the movable structure 60 is a drill head, the drill head may rotate in three dimensional space relative to the Z-field, causing the enclosure 14 and the Hall effect sensors 38 thereon move relative to the spherical magnet member 12, which generally maintains its initial orientation. Subjecting the magnetometer 10 to vibrations can help move the spherical magnet member 12 within the enclosure 14. Such vibrations can be imposed by equipment that the magnetometer 10 is secured to and/or a vibration source secured to the magnetometer.

Although the magnetometer 10 described as being mounted on a movable structure 60, the present invention is not limited in this regard and other embodiments, the magnetometer can be placed on a stationary structure 62 in proximity to the movable structure 60 as shown in FIG. 7, and the movable structure 60 is equipped so that changes in orientation relative to the magnetometer affect the prevailing magnetic field sensed by the spherical magnet member 12 therein. Such an arrangement is described herein as “sensing proximity” between the movable structure 60 and the magnetometer 10, indicated at S in FIG. 7. For example, in one embodiment, at least one magnet 60a is mounted on the movable structure 60 while the magnetometer 10 is mounted on a stationary structure 62 at a predetermined distance from, but within the field of, the at least one magnet. In another embodiment, the movable structure comprises a ferromagnetic material within sensing proximity to the magnetometer 10. When the ferromagnetic material moves, the spherical magnet member 12 amplifies an external magnetic field into a stronger magnetic field which is then applied to and sensed by the Hall effect sensors 38. In such an embodiment, a magnet is not needed on the movable structure.

The Hall effect sensors 38 sense generate voltage outputs in response to the change of orientation of the spherical magnet member 12 to the Hall effect sensors. The voltage outputs are analyzed by the circuit 46 to provide orientation data for the movable structure and or the spherical magnet member 12. The voltage outputs from the Hall effect sensors 38 are sufficiently large such that high accuracy and a wide error band can be achieved without the need for close manufacturing and/or assembly tolerances.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item.

Although the invention has been described with reference to particular embodiments thereof, it will be understood by one of ordinary skill in the art, upon a reading and understanding of the foregoing disclosure, that numerous variations and alterations to the disclosed embodiments will fall within the scope of this invention and of the appended claims.

What is claimed is:

1. A magnetometer comprising:
a spherical magnet member movably disposed within an enclosure;
a plurality of Hall effect sensors on the enclosure; and
circuitry responsive to the plurality of Hall effect sensors, the circuitry being configured to indicate changes in the relative orientation of the spherical magnet member and the plurality of Hall effect sensors.

2. The magnetometer of claim 1, wherein the spherical magnet member comprises a spherical permanent magnet.

3. The magnetometer of claim 1, wherein the spherical magnet member comprises a spherical permanent magnet.

4. The magnetometer of claim 1, wherein the spherical magnet member comprises a spherical permanent magnet having a plating material thereon.

5. The magnetometer of claim 1, wherein the spherical magnet member comprises a permanent magnet, a ballast element on the permanent magnet, and a shell around the permanent magnet and the ballast element, the shell having a spherical outer surface.

6. The magnetometer of claim 1, including a lubricant between the enclosure and the spherical magnet member.

7. The magnetometer of claim 6, wherein the lubricant comprises a layer of PTFE.

8. The magnetometer of claim 6, wherein the lubricant comprises a magnetic liquid.

9. A method of making a magnetometer, comprising:
providing a spherical magnet movably disposed within an enclosure;
disposing a plurality of Hall effect sensors on the enclosure; and
providing circuitry responsive to the plurality of Hall effect sensors, the circuitry being configured to indicate changes in the relative orientation of the spherical magnet member and the plurality of Hall effect sensors.

10. The method of claim 9 comprising attaching the plurality of Hall effect sensors to a flexible substrate and disposing the flexible substrate around the enclosure

11. A method of sensing a change in orientation of a movable structure, comprising:
placing a magnetometer as defined in claim 1 on the movable structure;
allowing the spherical magnet member in the enclosure to assume an initial orientation therein; and
monitoring the circuitry that is responsive to the Hall effect sensors.

12. A method of sensing a change in orientation of a movable structure, comprising:
placing a magnetometer as defined in claim 1 on a stationary structure in sensing proximity to the movable structure;
allowing the spherical magnet member in the enclosure to assume an initial orientation therein; and
monitoring the circuitry that is responsive to the Hall effect sensors.

13. The method of claim 12, wherein the movable structure has a magnet thereon in sensing proximity to the magnetometer.

14. The method of claim 12, wherein the movable structure comprises a ferromagnetic material in sensing proximity to the magnetometer.
